(19) United States
(12) Patent Application Publication
(10) Pub. No.: US 2025/0220995 A1
(43) Pub. Date: Jul. 3, 2025

(54) SILICON CARBIDE BASED SEMICONDUCTOR DEVICES WITH RING-SHAPED CHANNEL REGIONS AND/OR CHANNEL REGIONS THAT EXTEND IN MULTIPLE DIRECTIONS IN PLAN VIEW

(71) Applicant: Wolfspeed, Inc., Durham, NC (US)

(72) Inventor: Daniel Jenner Lichtenwalner, Raleigh, NC (US)

(21) Appl. No.: 18/403,068

(22) Filed: Jan. 3, 2024

(51) Int. Cl. H01L 29/10; H01L 29/16; H01L 29/739; H01L 29/78

(52) U.S. Cl. CPC H10D 62/235; H10D 30/615; H10D 30/668; H10D 12/441; H10D 62/8325

(57) ABSTRACT

A semiconductor device such as a MOSFET or IGBT comprises a semiconductor layer structure that includes a drift region having a first conductivity type, a plurality of channel regions that each have a second conductivity type, and a plurality of JFET regions that each have the first conductivity type. Each channel region comprises a ring-shaped channel region that has a ring shape and surrounds a respective one of the JFET regions when viewed in plan view.

### FIELD

The present invention relates to semiconductor devices and, more particularly, to power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region that is electrically connected to the source terminal and a drain region that is electrically connected to the drain terminal are formed in the semiconductor layer structure. A channel region is interposed in the semiconductor layer structure between the source region and the drain region. A gate electrode that is electrically connected to the gate terminal is disposed adjacent the channel region and separated from the channel region by a thin oxide layer. A MOSFET may be turned on or off by setting a gate bias voltage that is applied to the gate electrode (through the gate terminal) to be above or below a threshold value. When the gate bias voltage exceeds the threshold value, the MOSFET is turned on (i.e., it is in its “on-state”), and current is conducted through the channel region between the source and drain regions. When the gate bias voltage is reduced below the threshold level, the MOSFET turns off and current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate terminals may be on the top surface of the semiconductor layer structure and the drain terminal may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination structure such as, for example, guard rings or a junction termination extension, in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

One failure mechanism for a power MOSFET is the so-called “breakdown” of the gate oxide layer. The gate oxide layer is subjected to high electric fields during both on-state and off-state operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

FIG. 2A is a schematic plan view of a top surface of a portion of the semiconductor layer structure of a conventional silicon carbide power MOSFET 1. The dotted boxes in FIG. 2A illustrate the locations of the gate electrodes that are formed on top of the semiconductor layer structure in order to provide context. FIG. 2B is a cross-sectional view taken along line 2B-2B of FIG. 2A. The cross-section of FIG. 2B shows one full unit cell of the MOSFET 1 and portions of two adjacent unit cells. It should be noted that the cross-section of FIG. 2B is not taken along a straight line but instead includes a “jog” to show cross-sections of two different regions of the MOSFET 1.

Referring to FIGS. 2A-2B, the MOSFET 1 includes a heavily-doped n-type (n+) silicon carbide semiconductor substrate 10. A lightly-doped n-type (n) silicon carbide drift region 20 is provided on the upper surface of the substrate 10. An upper portion 22 of the drift region 20 may have a higher doping concentration of n-type dopants than the lower portion of the drift region 20. This more heavily doped upper portion of the drift region is typically referred to as a “current spreading layer” 22 and is considered to be part of the drift region 20. Moderately-doped (p) p-type wells 30 (also referred to as “p-wells”) are formed on or in upper portions of the n-type silicon carbide drift region 20. Upper portions 32 of the p-wells 30 act as channel regions for the MOSFET 1, as will be explained in more detail below. The channel regions 32 may be more lightly doped than the remainder of each p-well 30. The portions of the drift region 20 (or current spreading layer 22, if provided) that are in between the p-wells 30 are referred to as JFET regions 24. The JFET regions 24 are lightly to moderately doped n-type silicon carbide regions that are typically doped more heavily than the lower portion of the drift region 20.

Heavily-doped (n+) n-type silicon carbide source regions 40 are formed in upper portions of the p-wells 30. In addition, heavily-doped (p+) p-type silicon carbide well contact regions 38 are also formed in upper portions of the p-wells 30 and appear as “islands” in the source regions 40, as can be seen best in FIG. 2A. As shown in FIG. 2B, a source metallization layer 80 is formed on the source regions 40 and the well contact regions 38. As the source regions 40 and the well contact regions 38 are heavily doped regions, they may provide a low resistivity connection to the source metallization layer 80.

The substrate 10, drift region 20 (including any current spreading layer 22 and the JFET regions 24), the p-wells 30 (including the channel regions 32), the well contact regions 38 and the source regions 40 comprise a semiconductor layer structure 50 of MOSFET 1. A plurality of longitudinally-extending silicon oxide gate insulating layers 60 are formed on the upper surface of the semiconductor layer structure 50. A plurality of longitudinally-extending gate electrodes 70 are formed on the respective gate insulating layers 60 opposite the semiconductor layer structure 50. A plurality of intermetal dielectric patterns 62 cover the respective gate electrodes 70. Openings are provided between adjacent intermetal dielectric patterns 62 that expose the upper surface of the semiconductor layer structure 50. The source metallization layer 80 is formed on the intermetal dielectric patterns 62 and within these openings so as to contact the heavily-doped p-type well contact regions 38 and n-type source regions 40. A drain contact 6 is formed on the lower surface of the substrate 10. The channel regions 32 extend in the same direction as the gate electrodes 70, which may be referred to herein as a longitudinal direction.

As noted above, the upper side portions of each p-well 30 serve as channel regions 32 through which current flows during on-state operation of MOSFET 1. In particular, when a voltage that exceeds a threshold voltage of MOSFET 1 is applied to the gate electrodes 70, the channel regions 32 (which are positioned directly below the gate electrodes 70 with the gate oxide layers 60 interposed therebetween) are depleted thereby allowing current to flow from a source terminal of MOSFET 1, through the source metallization layer 80 and into the source regions 40, through the depleted channel regions 32 to the JFET regions 24, and then through the drift region 20 and substrate 10 to the drain contact 6. The bold arrow in FIG. 2B illustrates the current path through the left side of the “full” unit cell shown in FIG. 2B.

### SUMMARY

Pursuant to some embodiments of the present invention, semiconductor devices are provided that comprise a semiconductor layer structure comprising a drift region having a first conductivity type, a plurality of channel regions that each have a second conductivity type, and a plurality of JFET regions that each have the first conductivity type. Each channel region comprises a ring-shaped channel region that has a ring shape and surrounds a respective one of the JFET regions when viewed in plan view.

In some embodiments, the ring-shaped channel regions are arranged as a plurality of columns of ring-shaped channel regions when viewed in plan view. In some embodiments, the ring-shaped channel regions are also arranged as a plurality of rows of ring-shaped channel regions when viewed in plan view. In some embodiments, the ring-shaped channel regions in each row are offset from the ring-shaped channel regions in an adjacent row.

In some embodiments, the semiconductor device further comprises a source metallization layer that contacts an upper surface of the semiconductor layer structure in between first and second of the columns of ring-shaped channel regions.

In some embodiments, the semiconductor device further comprises a first gate electrode that extends on an upper surface of the semiconductor layer structure above a first of the columns of ring-shaped channel regions and a second gate electrode that extends on the upper surface of the semiconductor layer structure above a second of the columns of ring-shaped channel regions. A longitudinal axis of the first gate electrode may be parallel to a longitudinal axis of the second gate electrode. In some embodiments, the first gate electrode includes a plurality of first openings, where each first opening is above a respective one of the JFET regions. In some embodiments, a dielectric layer is formed on an upper surfaces of each of the JFET regions in the respective first openings. In some embodiments, the first gate electrode is separated from the second gate electrode in a transverse direction, and wherein a width of each ring-shaped channel region in the transverse direction is larger than a distance between adjacent ring-shaped channel regions in the first of the columns of ring-shaped channel regions.

In some embodiments, the semiconductor device further comprises a plurality of gate mesh segments that each extend on the upper surface of the semiconductor layer structure perpendicular to the longitudinal axes of the first and second gate electrodes.

In some embodiments, the ring-shaped channel regions are upper regions of a well region having the second conductivity type that is formed on the drift region, and the JFET regions are within openings in the well region. In some embodiments, the well region is a single continuous region within an active region of the semiconductor device. In some embodiments, the semiconductor layer structure further comprising a continuous source region that extends throughout the active region on the well region. In some embodiments, the continuous source region comprises a plurality of longitudinally-extending stripes and a plurality of transversely-extending connecting segments, and the transversely-extending connecting segments connect adjacent longitudinally-extending stripes. In some embodiments, a first of the transversely-extending connecting segments is interposed between adjacent first and second of the ring-shaped channel regions in a first column of ring-shaped channel regions.

In some embodiments, the semiconductor device further comprises a continuous gate electrode that extends throughout an active region of the semiconductor device. In some embodiments, the semiconductor layer structure further comprising a source region having the first conductivity type, and the gate electrode includes a plurality of second openings that expose portions of the source region that are in between adjacent pairs of ring-shaped channel regions. In some embodiments, each ring-shaped channel region has a hexagonal ring shape.

In some embodiments, the gate electrode includes a plurality of first openings that expose the respective JFET regions.

Pursuant to further embodiments of the present invention, semiconductor devices are provided that comprise a semiconductor layer structure comprising a drift region having a first conductivity type and a plurality of channel regions having a second conductivity type, where each channel region includes, in plan view, a first segment that extends in a first direction and a second segment that extends in a second direction that is different from the first direction, a first gate electrode that has a first longitudinal axis on an upper surface of the semiconductor layer structure, and a second gate electrode that has a second longitudinal axis on an upper surface of the semiconductor layer structure, the second longitudinal axis extending in parallel to the first longitudinal axis.

In some embodiments, the first and second longitudinal axes each extend in the first direction.

In some embodiments, the first direction is perpendicular to the second direction.

In some embodiments, each channel region is a ring-shaped channel region that has a ring shape when viewed in plan view. In some embodiments, the semiconductor layer structure further comprises a plurality of JFET regions that have the first conductivity type, and each ring-shaped channel region surrounds a respective one of the JFET regions when viewed in plan view. In some embodiments, the first gate electrode includes a plurality of first openings, where each first opening is above a respective one of the JFET regions. In some embodiments, a dielectric layer is formed on upper surfaces of each of the JFET regions in the respective first openings.

In some embodiments, the first gate electrode vertically overlaps a first sub-set of the ring-shaped channel regions, and the second gate electrode vertically overlaps a second sub-set of the ring-shaped channel regions. In some embodiments, the first sub-set of the ring-shaped channel regions defines a first column of ring-shaped channel regions and the second first sub-set of the ring-shaped channel regions defines a second column of ring-shaped channel regions. In some embodiments, the semiconductor device further comprises a source metallization layer that contacts an upper surface of the semiconductor layer structure in between adjacent first and second of the ring-shaped channel regions in the first column of ring-shaped channel regions.

In some embodiments, the first gate electrode is separated from the second gate electrode in a transverse direction, and wherein a width of each ring-shaped channel region in the transverse direction is larger than a distance between adjacent ring-shaped channel regions that are underneath the first gate electrode.

In some embodiments, the semiconductor device further comprises a plurality of gate mesh segments that each extend on the upper surface of the semiconductor layer structure perpendicular to the first and second longitudinal axes.

Pursuant to still further embodiments of the present invention, semiconductor devices are provided that comprise a semiconductor layer structure comprising a drift region having a first conductivity type and a plurality of ring-shaped channel regions having a second conductivity type, a gate electrode that covers the ring-shaped channel regions, and a source metallization layer that contacts an upper surface of the semiconductor layer structure in between two adjacent ring-shaped channel regions.

In some embodiments, the semiconductor layer structure further comprises a plurality of JFET regions, where each ring-shaped channel region surrounds a respective one of the JFET regions. In some embodiments, the gate electrode covers the entirety of each JFET region. In some embodiments, first openings are provided in the gate electrode above each JFET region. In some embodiments, a dielectric layer is formed on an upper surface of each of the JFET regions in the respective first openings. In some embodiments, the gate electrode comprises a single gate electrode that extends continuously throughout the active region, the gate electrode including a plurality of second openings, and the source metallization layer extending into the second openings. In some embodiments, the gate electrode includes a plurality of first openings are provided above each JFET region. In some embodiments, the first openings are aligned in a plurality of rows. In some embodiments, the first openings are also aligned in a plurality of columns. In some embodiments, the first openings in each row are offset from the first openings in a respective adjacent row.

Pursuant to additional embodiments of the present invention, semiconductor devices are provided that comprise a semiconductor layer structure comprising a drift region having a first conductivity type, a continuous well region having a second conductivity type on the drift region, and a plurality of discontinuous JFET regions having the first conductivity type, the JFET regions arranged in a plurality of rows and a plurality of columns, a continuous gate electrode that extends over the semiconductor layer structure, the gate electrode including a plurality of second openings, and a source metallization layer that extends into the second openings.

In some embodiments, the gate electrode further includes a plurality of first openings, each first opening exposing a respective one of the JFET regions. In some embodiments, a dielectric layer is formed on an upper surface of each of the JFET regions in the respective first openings.

In some embodiments, the JFET regions in a first of the rows are offset in a row direction from the JFET regions in an adjacent row.

In some embodiments, the semiconductor layer structure further comprises a plurality of ring-shaped channel regions that each surround a respective one of the JFET regions when the semiconductor device is viewed in plan view. In some embodiments, the second openings are outside the ring-shaped channel regions when the semiconductor device is viewed in plan view.

Pursuant to other embodiments of the present invention, semiconductor devices are provided that comprise a semiconductor layer structure comprising a drift region having a first conductivity type, a well region having a second conductivity type on the drift region, and a plurality of spaced-apart JFET regions having the first conductivity type, a first gate electrode that extends on an upper surface of the semiconductor layer structure above a first sub-set of the spaced-apart JFET regions, and a second gate electrode that extends on an upper surface of the semiconductor layer structure above a second sub-set of the spaced-apart JFET regions. A longitudinal axis of the first gate electrode is parallel to a longitudinal axis of the second gate electrode.

In some embodiments, the first gate electrode includes a plurality of first openings, where each first opening is above a respective one of the JFET regions. In some embodiments, a dielectric layer is formed on an upper surface of each of the JFET regions in the respective first openings.

In some embodiments, the semiconductor layer structure further comprises a plurality of ring-shaped channel regions that are provided in an upper portion of the well region, where each ring-shaped channel region surrounds a respective one of the JFET regions when the semiconductor device is viewed in plan view. In some embodiments, the first gate electrode is separated from the second gate electrode in a transverse direction, and wherein a width of each ring-shaped channel region in the transverse direction is larger than a distance between adjacent ones of the ring-shaped channel regions that vertically overlap the first gate electrode.

In some embodiments, the semiconductor device further comprises a plurality of gate mesh segments that each extend on the upper surface of the semiconductor layer structure perpendicular to the longitudinal axes of the first and second gate electrodes.

In some embodiments, the semiconductor layer structure further comprising a continuous source region that extends throughout the active region on the well region. In some embodiments, the continuous source region comprises a plurality of longitudinally-extending stripes and a plurality of transversely-extending connecting segments, and the transversely-extending connecting segments connect adjacent longitudinally-extending stripes.

Pursuant to yet additional embodiments of the present invention, semiconductor devices are provided that comprise a semiconductor layer structure comprising a drift region having a first conductivity type and a plurality of ring-shaped channel region having a second conductivity type on the drift region, where a first plurality of gate openings are provided in an upper surface of the semiconductor layer structure and a gate electrode that extends into the gate openings in the first plurality of gate openings.

In some embodiments, each ring-shaped channel region surrounds a respective one of the first plurality of gate openings when the semiconductor device is viewed in plan view.

In some embodiments, the gate electrode is a first gate electrode, the semiconductor device further comprising a second gate electrode that extends in parallel to the first gate electrode. In some embodiments, a second plurality of gate openings are provided in an upper surface of the semiconductor layer structure and the second gate electrode extends into the gate openings in the second plurality of gate openings. In some embodiments, the semiconductor layer structure further comprises a continuous well region having the second conductivity type that extends underneath both the first and second gate electrodes.

Pursuant to still additional embodiments of the present invention, semiconductor devices are provided that comprise a semiconductor layer structure comprising a drift region having a first conductivity type, a well region having a second conductivity type on the drift region and a source region having first conductivity type in the well region, where a plurality of gate openings are provided in an upper surface of the semiconductor layer structure, the gate openings arranged to form a plurality of columns of gate openings.

In some embodiments, the semiconductor device further comprises a gate electrode that extends into the gate openings.

In some embodiments, the semiconductor device further comprises a plurality of ring-shaped channel regions that surround the respective gate openings.

### BRIEF DESCRIPTION OF DRAWINGS

FIG. 1 is a semi-log graph illustrating the relationship between the lifetime of the gate oxide layer as a function of applied electric field strength

FIG. 2A is a schematic plan view of a portion of a top surface of the semiconductor layer structure of a conventional power MOSFET.

FIG. 2B is a schematic cross-sectional view taken along the line 2B-2B of FIG. 2A with portions of the upper metallization and dielectric layers of the power MOSFET added for context.

FIG. 3A is a schematic top view of a silicon carbide power MOSFET according to certain embodiments of the present invention.

FIG. 3B is a schematic top view of the silicon carbide power MOSFET of FIG. 3A with various of the upper metal and dielectric layers removed.

FIG. 3C is a schematic top view of the portion of the silicon carbide power MOSFET of FIG. 3B shown in the box labelled A in FIG. 3B.

FIGS. 3D and 3E are schematic cross-sectional views taken along the lines 3D-3D and 3E-3E, respectively, of FIG. 3C with portions of the upper metallization and dielectric layers of the power MOSFET added for context.

FIG. 4A is a schematic plan view of a portion of a top surface of a semiconductor layer structure of a power MOSFET according to further embodiments of the present invention.

FIG. 4B is a schematic cross-sectional view taken along the line 4B-4B of FIG. 4A with portions of the upper metallization and dielectric layers of the power MOSFET added for context.

FIG. 5A is a schematic plan view of a portion of a top surface of the semiconductor layer structure of a power MOSFET according to additional embodiments of the present invention.

FIG. 5B is a schematic cross-sectional view taken along the line 5B-5B of FIG. 5A with portions of the upper metallization and dielectric layers of the power MOSFET added for context.

FIG. 6A is a schematic plan view of a portion of a top surface of a power MOSFET according to still further embodiments of the present invention with certain of the upper metallization and dielectric layers omitted.

FIG. 6B is a schematic cross-sectional view taken along the line 6B-6B of FIG. 6A with the upper metallization and dielectric layers of the power MOSFET added for context.

FIG. 7A is a schematic plan view of a portion of a top surface of the semiconductor layer structure of a power MOSFET according to additional embodiments of the present invention.

FIGS. 7B and 7C are schematic cross-sectional views taken along the lines 7B-7B and 7-7C, respectively, of FIG. 7A with portions of the upper metallization and dielectric layers of the power MOSFET added for context.

FIG. 7D is a schematic horizontal cross-section taken along line 7D-7D of FIG. 7B.

FIG. 7E is a schematic cross-sectional view of a modified version of the power MOSFET of FIGS. 7A-7D where FIG. 7E corresponds to the cross-section of FIG. 7B.

FIG. 8A is a schematic plan view of a portion of a power MOSFET according to still further embodiments of the present invention with certain of the upper metallization and dielectric layers omitted.

FIG. 8B is a schematic cross-sectional view taken along the line 8B-8B of FIG. 8A with the upper metallization and dielectric layers of the power MOSFET added for context.

FIG. 9A is a schematic plan view of a portion of a top surface of the semiconductor layer structure of a power MOSFET according to still further embodiments of the present invention.

FIG. 9B is a schematic cross-sectional view taken along line 9B-9B of FIG. 9A with portions of the upper metallization and dielectric layers of the power MOSFET added for context.

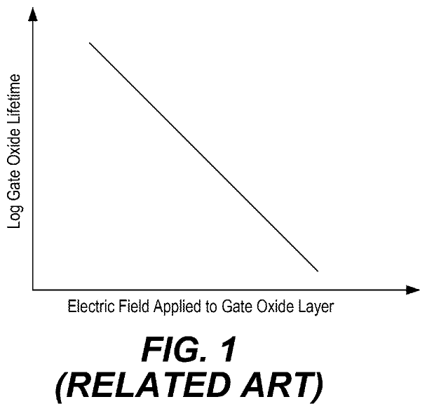

### DETAILED DESCRIPTION

There is an inherent tradeoff in vertical power silicon carbide MOSFETs between the on-state resistance and the reliability of the device. As discussed above, the gate oxide layer of a vertical power silicon carbide MOSFET will ultimately fail if subjected to high electric fields for too much time. One way to improve the reliability of an n-type vertical power silicon carbide MOSFET is to reduce the doping concentration of the n-type semiconductor regions that are adjacent the gate oxide layers, as the lower doping concentration levels acts to reduce the electric field levels in these semiconductor regions and the gate oxide layer during reverse blocking operation. Unfortunately, however, the n-type semiconductor regions that are adjacent the gate oxide layers are typically part of the on-state current conduction path, and the reduction in the doping concentration of these regions acts to increase the on-state resistance of the MOSFET. The increase in the on-state resistance increases conduction losses and reduces switching speeds, both of which are undesirable.

Pursuant to embodiments of the present invention, vertical power silicon carbide MOSFETs and other vertical power semiconductor devices (e.g., IGBTs) are provided that have improved on-state resistance performance that is provided by increasing the amount of channel area without increasing the size of the device. In some embodiments, the MOSFETs may also have lower electric fields in the gate oxide layers during reverse blocking operation, and hence may also exhibit improved reliability.

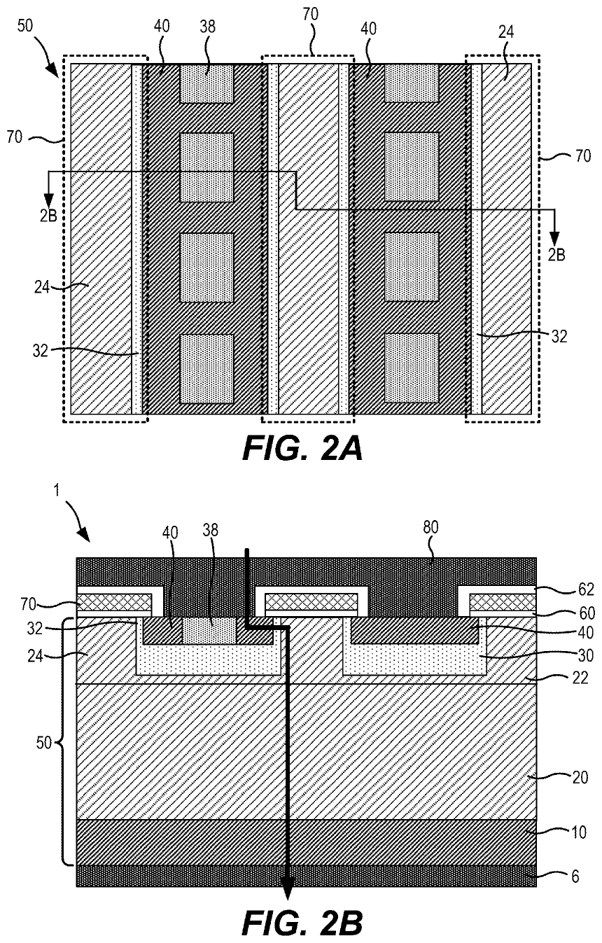

The conventional vertical power MOSFET discussed above with respect to FIGS. 2A-2B has longitudinally-extending well and source regions and a plurality of longitudinally-extending gate electrodes, all of which extend in the same direction. Vertical power MOSFETs having such longitudinally-extending well regions, source regions and gate electrodes are referred to as having a “stripe configuration” since the gate electrodes, well regions and source regions are generally formed as stripes of material. Some embodiments of the present invention leverage the fact that the amount of channel area in a MOSFET having a “striped” configuration may be increased by modifying the conventional striped design to instead have ring-shaped channel regions. As discussed above with reference to FIGS. 2A-2B, in a conventional vertical power MOSFET having a striped configuration, two channel regions are provided underneath each gate electrode and extend continuously in the longitudinal direction of the gate electrode. Thus, each channel region extends continuously in the same direction. In vertical power MOSFETs according to certain embodiments of the present invention, the pair of conventional channel regions that are provided underneath each gate electrode are replaced with a larger number of ring-shaped channel regions that have ring-shaped channel regions when viewed in plan view. Each ring-shaped channel region may surround a respective one of the JFET regions when viewed in plan view. Properly designed, this increases the amount of channel region, which reduces the on-state resistance. In addition, openings may optionally be provided in the gate electrodes that expose portions of each JFET region, which acts to reduce the electric field levels in the portions of the gate oxide layers that tend to experience the highest electric field levels during reverse blocking operation. This may improve the reliability of the devices. While the openings in the gate electrodes increase the gate resistance, the size of the openings and the number of openings may be selected so as to optimize tradeoffs between gate resistance, on-state resistance and reliability for devices designed for different applications.

Pursuant to further embodiments of the present invention, improved power MOSFETs having cell configurations are provided. Power MOSFETs having well regions formed as spaced-apart islands are referred to as having a “cell configuration.” MOSFETs having cell configurations may provide higher cell (or MOS channel) packing density than MOSFETs having the more conventional stripe configuration that is discussed above. While some conventional vertical power MOSFETs that have a cell configuration have ring-shaped channel regions, these devices are configured so that the source metallization layer contacts the semiconductor layer structure within the interiors of the ring-shaped channel regions, Pursuant to embodiments of the present invention, vertical power MOSFETs are provided in which the JFET regions are positioned within the interiors of the ring-shaped channel regions when the device is viewed in plan view, and the source metallization layer contacts the semiconductor layer structure through openings in the gate electrode that are formed outside of the ring-shaped channel regions when the device is viewed in plan view.

The techniques disclosed herein may be used in power MOSFETs having either planar gate electrodes or trench gate designs.

The power MOSFET's and other power semiconductor devices according to embodiments of the present invention may exhibit reduced on-state resistance while maintaining or even improving device reliability. While reducing the size of the JFET region acts to increase the on-state resistance in the JFET portion of the on-state current path, this increase may be mitigated or even eliminated by the reduction in the on-resistance of the channel portion of the current path that is provided by the increase in channel area. Moreover, the power semiconductor devices according to embodiments of the present invention may also exhibit improved behavior under short circuit conditions since these devices replace portions of the JFET regions of conventional devices with channel regions. Under high drain bias, the JFET regions in conventional vertical silicon carbide power semiconductor devices tends to pinch off and become more resistive. Thus, under short circuit conditions (gate biased “on” with high Vds applied), decreasing the JFET region area will increase the resistance, which acts to limit the short circuit Ids current and therefore increases the time before failure occurs under short circuit conditions.

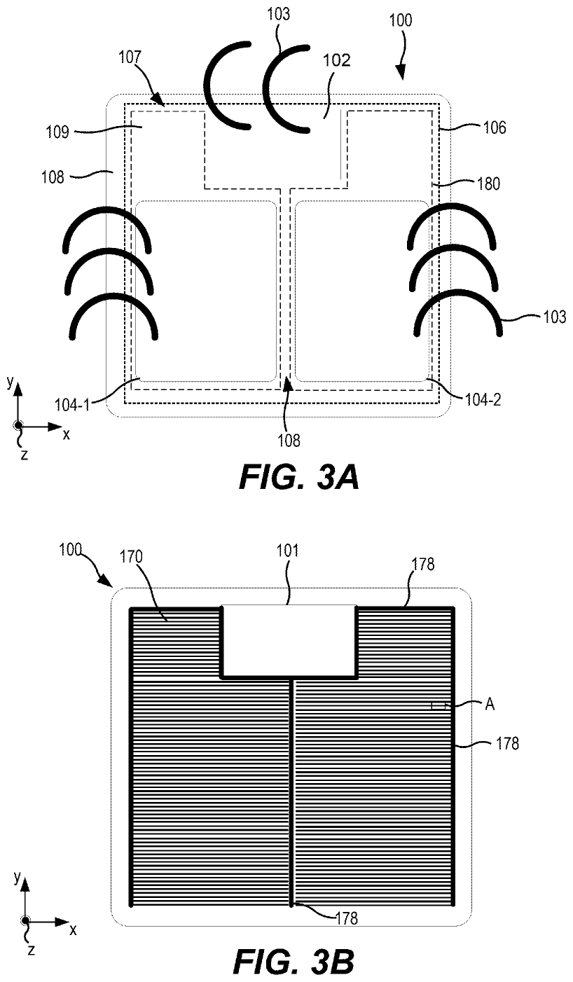

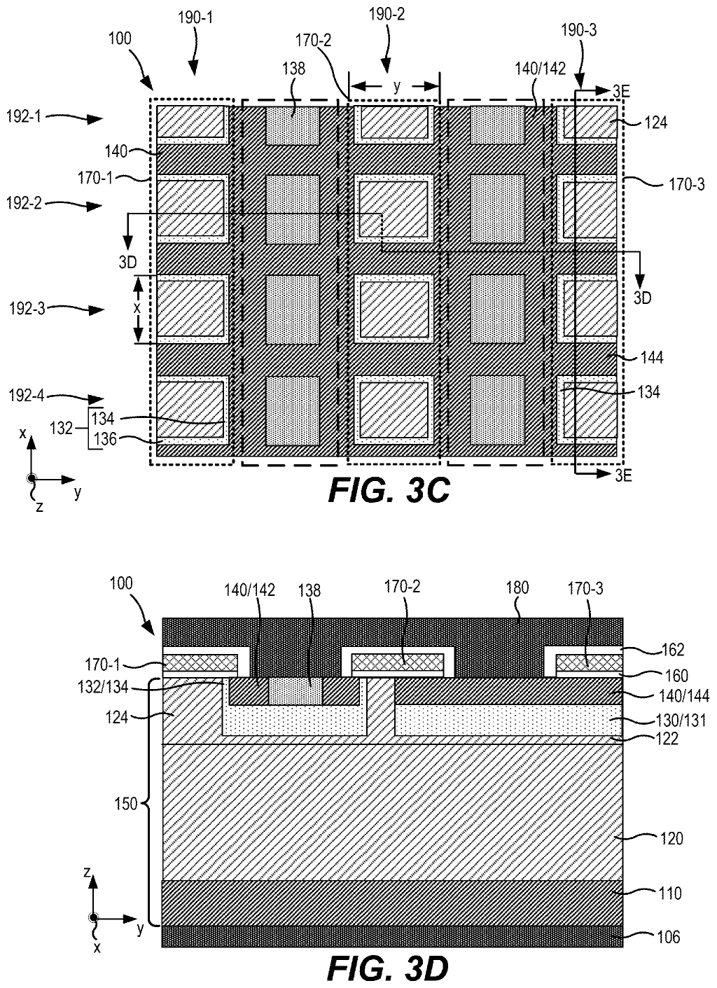

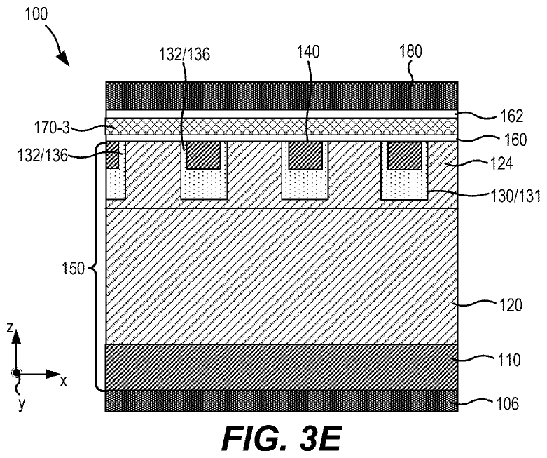

Example embodiments of power semiconductor devices according to embodiments of the present invention will now be described with reference to FIGS. 3A-8B. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate-controlled thyristors and the like.

FIG. 3A is a schematic top view of a vertical silicon carbide power MOSFET 100 according to certain embodiments of the present invention. FIG. 3B is a schematic plan view of the power MOSFET 100 with various top-side metal and dielectric layers thereof omitted to show the gate electrodes and gate buses. FIG. 3C is a schematic top view of the portion of the power MOSFET 100 of FIG. 3B shown in the box labelled A in FIG. 3B. FIGS. 3D-3E are schematic cross-sectional views of about two unit cells of the power MOSFET 100 that is taken along lines 3D-3D and 3E-3E, respectively, of FIG. 3C. It will be appreciated that the thicknesses of various of the layers and regions in FIGS. 3A-3E are not necessarily drawn to scale. The same is true with respect to the other figures included in this application.

The power MOSFET 100 includes a semiconductor layer structure 150 (see FIGS. 3D-3E) that comprises one or more semiconductor substrates and/or layers. At least one of the semiconductor layers in the semiconductor layer structure 150 may be a silicon carbide layer. Various metal and/or dielectric layers are formed on either side of the semiconductor layer structure 150 and embedded in the semiconductor layer structure 150.

As shown in FIG. 3A, the top-side metal layers include a gate bond pad 102 and one or more source bond pads 104-1, 104-2 that are formed on the upper side of the semiconductor layer structure 150. A metal drain pad 106 (shown as a dotted box in FIG. 3A, and fully visible in FIGS. 3D-3E) is provided on the bottom side of the semiconductor layer structure 150. The gate bond pad 102, the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization layer 180 (indicated by the dashed boxes in FIG. 3A) that electrically connects certain regions of the semiconductor layer structure 150 to the source bond pads 104-1, 104-2. The source bond pads 104-1, 104-2 may be portions of the source metallization layer 180 that are exposed through openings in the protective layer 109 or may be separate metal layers. The source metallization layer 180 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 103 are shown in FIG. 3A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 3B is another plan view of power MOSFET 100 with the gate and source bond pads 102, 104, the polyimide layer 109, the source metallization layer 180, the intermetal dielectric layers 162 and various other metal and dielectric layers removed to show the gate electrodes 170 that are formed on the upper surface of the semiconductor layer structure 150. A patterned field oxide layer (not shown) is formed on the semiconductor layer structure 150 in the inactive region 108 of the MOSFET 100. The field oxide layer may be a relatively thick oxide layer (e.g., ten to twenty times thicker than the gate oxide layers that are discussed below). A polysilicon layer 101 may be formed on the field oxide layer and may be formed in the region where the gate bond pad 102 is formed so that the gate bond pad 102 vertically overlaps the field oxide layer and the polysilicon layer 101. As used herein, two elements of a semiconductor device are considered to “vertically overlap” if an axis that is perpendicular to the major surfaces of a semiconductor layer structure of the semiconductor device intersects both elements.

One or more gate buses 178 are provided that extend around the periphery of the active region 107. The field oxide layer also typically runs underneath each gate bus 178. The gate buses 178 are electrically connected to the gate bond pad 102, often through gate resistors (not shown). A plurality of gate electrodes 170 are formed throughout the active region 107 on the upper surface of the semiconductor layer structure 150. In the depicted power MOSFET 100, the gate electrodes 170 extend horizontally across the semiconductor layer structure 150. In other cases, the gate electrodes 170 may extend vertically across the semiconductor layer structure 150, or both horizontally-extending and vertically-extending gate electrodes 170 can be provided to form a grid-like gate electrode structure. The gate electrodes 170 may be connected to the gate pad 102 through the gate buses 178. The gate electrodes 170 may comprise, for example, a doped polysilicon pattern. The gate buses 178 may comprise polysilicon and/or metal structures in example embodiments and typically are in the inactive region 108 of power MOSFET 100.

FIG. 3C is a schematic top view of the upper surface of the semiconductor layer structure 150 of the portion of the silicon carbide power MOSFET 100 of FIG. 3B that is shown in the box labelled A in FIG. 3B. It should be noted that the view of FIG. 3C is rotated 90° relative to the box A in FIG. 3B. The dotted boxes in FIG. 3C illustrate the locations of the gate electrodes 170 and the dashed boxes illustrate the locations where the source metallization layer 180 directly contacts the upper surface of the semiconductor layer structure 150. FIG. 3D is a cross-sectional view taken along line 3D-3D of FIG. 3C. The cross-section of FIG. 3D shows one full unit cell of the MOSFET 100 and portions of two adjacent unit cells. It should be noted that the cross-section of FIG. 3D is not taken along a straight line but instead includes a “jog” to show cross-sections of two different regions of the MOSFET 100. FIG. 3E is a cross-sectional view taken along line 3E-3E of FIG. 3C. The cross-section of FIG. 3E is taken through one of the gate electrodes 170 along the longitudinal axis of the gate electrode 170. Note that FIGS. 3D and 3E illustrate the metal and dielectric layers that are formed on the upper surface of the semiconductor layer structure 150.

Referring to FIGS. 3C-3E, the power MOSFET 100 includes an n-type silicon carbide semiconductor substrate 110 such as, for example, a single crystal 4H silicon carbide semiconductor substrate that is heavily-doped with n-type impurities. The n-type doping concentration of the substrate 110 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., be graded with depth), and the doping concentration refers to the peak doping concentration of the layer or region. For an n-type semiconductor material, references to the doping concentration refer to the concentration of n-type dopants and for a p-type semiconductor material, references to the doping concentration refer to the concentration of p-type dopants. The substrate 110 may be any appropriate thickness (e.g., between 100 and 500 microns thick), and it will be appreciated that the substrate 110 will typically be much thicker than shown. The thickness of various other layers of power MOSFET 100 likewise may not be shown to scale in order to allow other portions of the devices to be enlarged in the figures. The substrate 110 may be partially or fully removed in some embodiments.

A lightly-doped n-type silicon carbide drift region 120 is provided on the upper surface of the substrate 110. The n-type silicon carbide drift region 120 may be formed by, for example, epitaxial growth on the silicon carbide substrate 110. The n-type silicon carbide drift region 120 may have, for example, a doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 120. For example, a MOSFET having a voltage blocking rating of 10 kV or more might have a drift region n-type doping concentration of between 1×10¹⁴ to 5×10¹⁴ dopants/cm³, whereas a MOSFET having a voltage blocking rating of 500-1200 V might have a drift region n-type doping concentration of between 1×10¹⁶ to 5×10¹⁶ dopants/cm³. The n-type silicon carbide drift region 120 may be a thick region, having a vertical height above the substrate 110 of, for example, 3-50 microns. An upper portion 122 of the n-type silicon carbide drift region 120 may be more heavily doped than the remainder of the drift region 120 to provide a current spreading layer 122 in an upper portion of the drift region 120. The doping concentration of this current spreading layer 122 may be, for example, about 1.5 to 4.0 times higher than the doping concentration of the remainder of the drift region 120. The current spreading layer 122 may be formed during the epitaxial growth process. Herein, the current spreading layer 122, if provided, is considered to be part of the drift layer 120 and hence will not be discussed separately.

A continuous p-type well region 130 (which may also be referred to herein as a “p-well”) is formed in an upper portion of the n-type drift region 120 throughout the active region 107 (and into the inactive region). The p-well 130 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-well 130 may be formed via ion implantation. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. The dopants may comprise, for example, Al⁺ or N⁺ ions, although any appropriate dopant ions may be used. In some embodiments, the implantation may be performed at different temperatures such as, for example, temperatures of 75° C. or more. It will be appreciated that the p-well 130 typically has a doping concentration that varies with depth. Channel regions 132 (discussed in more detail below) of the p-well 130 may be less heavily doped than other portions of the p-well 130.

A plurality of n-type JFET regions 124 are defined in the upper portion of the drift region 120. Each JFET region 124 may comprise a region of n-type material that is typically more heavily doped n-type than the lower portion of the drift region 120.

A continuous heavily-doped n-type silicon carbide source region 140 is formed in upper portions of the p-wells 130. The source region 140 may have a doping concentration of, for example, between 5×10¹⁸ cm⁻³ and 5×10²¹ cm⁻³. In addition, heavily-doped p-type silicon carbide well contact regions 138 are also formed in upper portions of the p-wells 130. The source region 140 may be a single continuous source region 140 that extends throughout the active region 107 on/in the p-well 130, and may be formed in the p-well 130 adjacent the source regions 140. The well contact regions 138 may appear as a plurality of “islands” in the source region 140 when the MOSFET 100 is viewed in plan view. It will be appreciated, however, that in other embodiments the well contact regions 138 may connect to each other along the x-direction so that a single elongated well contact region 138 is provided between each pair of adjacent gate electrodes 170. The well contact regions 138 and the source region 140 may each be formed via ion implantation. The substrate 110, the drift region 120 (including any current spreading layer 122 and the JFET regions 124), the p-well 130, the channel regions 132, the well contact regions 138 and the source region 140 together comprise the semiconductor layer structure 150 of MOSFET 100.

As shown in FIGS. 3D-3E, a plurality of gate dielectric layers 160 are formed on the upper surface of the semiconductor layer structure 150. The gate dielectric layers 160 may or may not be connected to each other along the periphery of the MOSFET 100. The gate dielectric layers 160 may comprise, for example, silicon oxide layers, although other insulating materials may be used. A plurality of gate electrodes 170 are formed on the respective gate dielectric layers 160. The gate electrodes 170 may comprise, for example, a conductive material such as polysilicon, a silicide or a metal. A plurality of intermetal dielectric layers 162 may cover the respective gate electrodes 170. The intermetal dielectric layers 162 may comprise, for example, silicon oxide. The gate dielectric layers 160, the gate electrodes 170 and the intermetal dielectric layers 162 each extend as stripes of material into the page in the view of FIG. 3D.

The upper surface of the semiconductor layer structure 150 is exposed in between adjacent intermetal dielectric patterns 162. The source regions 140 and the p-type well contact layers 138 are thus exposed in between the intermetal dielectric patterns 162. A source metallization layer 180 is formed over the upper surface of the device so that the source metallization layer 180 makes electrical contact to the n-type source regions 140 and the p-type well contact layers 136 while being electrically insulated from the gate electrodes 170 by the intermetal dielectric patterns 162. The source metallization layer 180 may comprise, for example, metals such as nickel, titanium, tungsten and/or aluminum, and/or alloys and/or thin layered stacks of these and/or similar materials. A drain contact 106 is formed on the lower surface of the substrate 110. The drain contact 106 may comprise, for example, the same or similar materials to the source metallization layer 180, and may form an ohmic contact to the silicon carbide substrate 110.

Referring to FIGS. 3C and 3E, the power MOSFET 100 differs from the conventional power MOSFET 1 of FIGS. 2A-2B in that power MOSFET 100 in several important ways. First, power MOSFET 100 includes enclosed looped or “ring-shaped” channel regions 132 (when viewed in plan view) that include both longitudinal channel segments 134 and transverse channel segments 136, as can best be seen in FIG. 3C. In addition, instead of having a single longitudinally-extending stripe shaped JFET region 24 under each gate electrode 62 as is the case of power MOSFET 1 of FIGS. 2A-2B, power MOSFET 100 includes a plurality of JFET regions 124 underneath each gate electrode 170 so that power MOSFET 100 includes a plurality of spaced-apart JFET regions 124. As can best be seen in FIG. 3C, each ring-shaped channel region 132 surrounds a respective one of the JFET regions 124 when the semiconductor layer structure 150 is viewed from above in plan view. Another difference between conventional power MOSFET 1 and power MOSFET 100 is that power MOSFET 100 has a single continuous p-well 130 that includes portions 131 that extend underneath the gate electrodes 170 in regions where the ring-shaped channel regions 132 are not present. The source region 140 in power MOSFET 100 is also a continuous region that includes portions 144 that extend above the portions 131 of the p-wells that extend underneath the gate electrodes 170 in regions where the ring-shaped channel regions 132 are not present.

As shown in FIG. 3C, the ring-shaped channel regions 132 that are provided underneath each gate electrode 170 may be arranged in columns 190 (in FIG. 3C three columns 190-1, 190-2, 190-3 of ring-shaped channel regions 132 are shown). The ring-shaped channel regions 132 may also be arranged in a plurality of rows 192 (in FIG. 3C four rows 192-1, 192-2, 192-3, 192-4 of ring-shaped channel regions 132 are shown). As shown in FIG. 3C, adjacent ring-shaped channel regions 132 are spaced apart from each other in the column direction by a distance “x,” and the transverse channel segments 136 have a transverse width of “y.” As is readily apparent, so long as y is greater than x, then power MOSFET 100 will have more channel area than conventional power MOSFET 1. In the depicted embodiment, y is about 2*x, and the total channel area of power MOSFET 100 exceeds the channel area of conventional power MOSFET 1 by about a factor of 1.4.

The increased channel area realized in power MOSFET 100 acts to decrease the on-state resistance of the channel region of power MOSFET 100 as compared to conventional power MOSFET 1. However, the total area of the JFET regions 124 of power MOSFET 100 is less than the total area of the JFET regions 24 of power MOSFET 1, which means that the on-state resistance of the JFET regions 124 of power MOSFET 100 may exceed the on-state resistance of the JFET regions 24 of power MOSFET 1. The power MOSFET 100 may be designed so that the reduction in the on-state resistance from the increase in channel area exceeds the increase in the on-state resistance that results from the reduced JFET area, so that power MOSFET 100 has a lower on-state resistance than conventional power MOSFET 1.

In addition, power MOSFET 100 may exhibit improved performance during short circuit conditions as compared to conventional power MOSFET 1. In particular, as discussed above, in the power MOSFET 100 the amount of JFET region 124 is decreased as compared to the conventional power MOSFET 1, while the amount of channel region 132 is increased. Under high drain bias, the JFET regions in conventional vertical silicon carbide power semiconductor devices tends to pinch off and become more resistive. Thus, under short circuit conditions (gate biased “on” with high Vds applied), decreasing the JFET region area will increase the resistance, which acts to limit the short circuit Ids current and allow for longer times in short circuit before failure occurs.

Under avalanche breakdown conditions when the drain bias exceeds the capability of the silicon carbide semiconductor layer structure to block voltage, the gridded structure of the P-regions around the isolated JFET openings (where the P implants connect with the drift region n-type material) can help distribute the avalanche breakdown current, and would allow avalanche current to spread more evenly across a device during this event, adding to the ruggedness of the device during avalanche breakdown conditions.

Referring again to FIGS. 3A-3E, pursuant to some embodiments of the present invention, semiconductor devices such as power MOSFET 100 are provided that comprise a semiconductor layer structure 150 that includes a drift region 120 having a first conductivity type (e.g., n-type), a plurality of channel regions 132 having a second conductivity type (e.g., p-type), and a plurality of JFET regions 124 having the first conductivity type (e.g., n-type). Each channel region 132 comprises a ring-shaped channel region 132 that has a ring shape when viewed in plan view (i.e., from above) and surrounds a respective one of the JFET regions 124 when viewed in plan view.

In some embodiments, the ring-shaped channel regions 124 may be arranged in a plurality of columns 190 of ring-shaped channel regions 132 when viewed in plan view and/or in a plurality of rows 192 of ring-shaped channel regions 132 when viewed in plan view. The MOSFET 100 may further comprise a source metallization layer 180. The source metallization layer 180 may contact an upper surface of the semiconductor layer structure 150 in between first and second of the ring-shaped channel regions that are in adjacent columns 190.

The MOSFET 150 may also include a first gate electrode 170 that extends on an upper surface of the semiconductor layer structure 150 above a first of the columns 190-1 of ring-shaped channel regions 132 and a second gate electrode 170 that extends on an upper surface of the semiconductor layer structure 150 above a second of the columns 190-2 of ring-shaped channel regions 132. A longitudinal axis of the first gate electrode 170 may be parallel to a longitudinal axis of the second gate electrode 170. The first gate electrode 170 may be separated from the second gate electrode 170 in a transverse direction, and a width of each ring-shaped channel region 132 in the transverse direction is larger than a distance between adjacent ring-shaped channel regions 132 in the first of the columns 190-1 of ring-shaped channel regions 132. As discussed above, this configuration can increase the overall amount of channel region as compared to MOSFETs that have conventional channels that only extend in one direction.

The ring-shaped channel regions 132 may be upper regions of a well region 130 having the second conductivity type that is formed on the drift region 120, and the JFET regions 124 may be positioned within openings in the well region 130 so that the ring-shaped channel regions 132 surround the respective JFET regions 124 when MOSFET 100 is viewed from above. The well region 130 may be a single continuous region within an active region of the MOSFET 100. A continuous source region 140 may also extend throughout the active region of the MOSFET 100 on the well region 130. The continuous source region 140 may comprise a plurality of longitudinally-extending stripes 142 and a plurality of transversely-extending connecting segments 144. The transversely-extending connecting segments 144 may connect adjacent longitudinally-extending stripes 142 to form the continuous source region 140. Each transversely-extending connecting segment 144 may extend underneath a gate electrode 170 to connect a first of the longitudinally-extending stripes 142 to a second of the longitudinally-extending stripes 142. A first of the transversely-extending connecting segments 144 may be interposed between first and second adjacent ring-shaped channel regions 132 in a first of the columns 190 of ring-shaped channel regions 132.

Still referring to FIGS. 3A-3E, it can be seen that pursuant to further embodiments of the present invention, semiconductor devices such as power MOSFET 100 are provided that comprise a semiconductor layer structure 150 that has a drift region 120 having a first conductivity type (e.g., n-type) and a plurality of channel regions 132 having a second conductivity type (e.g., p-type), where each channel region 132 includes, in plan view, a first segment 134 that extends in a first direction and a second segment 136 that extends in a second direction that is different from the first direction. The MOSFET 100 further comprises a first gate electrode 170-1 that extends in a longitudinal direction (x-direction) on an upper surface of the semiconductor layer structure 150 and a second gate electrode 170-2 that extends in the longitudinal direction (x-direction) on the upper surface of the semiconductor layer structure 150 in parallel to the first gate electrode 170-1.

In some embodiments, the longitudinal direction may be the first direction and/or the first direction may be perpendicular to the second direction. The channel regions 132 may be ring-shaped channel regions 132 that each has a ring shape when viewed in plan view. The ring-shape may be a rectangular ring, a rectangular ring with rounded corners, a hexagonal ring, a circular ring, an octagonal ring or any other closed ring shape.

Still referring to FIGS. 3A-3E, pursuant to still further embodiments of the present invention, semiconductor devices such as MOSFET 100 are provided that comprise a semiconductor layer structure 150 that has a drift region 120 having a first conductivity type and a plurality of ring-shaped channel regions 132 having a second conductivity type. A gate electrode 170 covers the ring-shaped channel regions 132, and a source metallization layer 180 contacts an upper surface of the semiconductor layer structure 150 in between respective pairs of adjacent ring-shaped channel regions 132.

The semiconductor layer structure 150 may further comprise a plurality of JFET regions 124, and each ring-shaped channel region 132 may surround a respective one of the JFET regions 124. In some embodiments, the gate electrode 170 may cover the entirety of each JFET region 124.

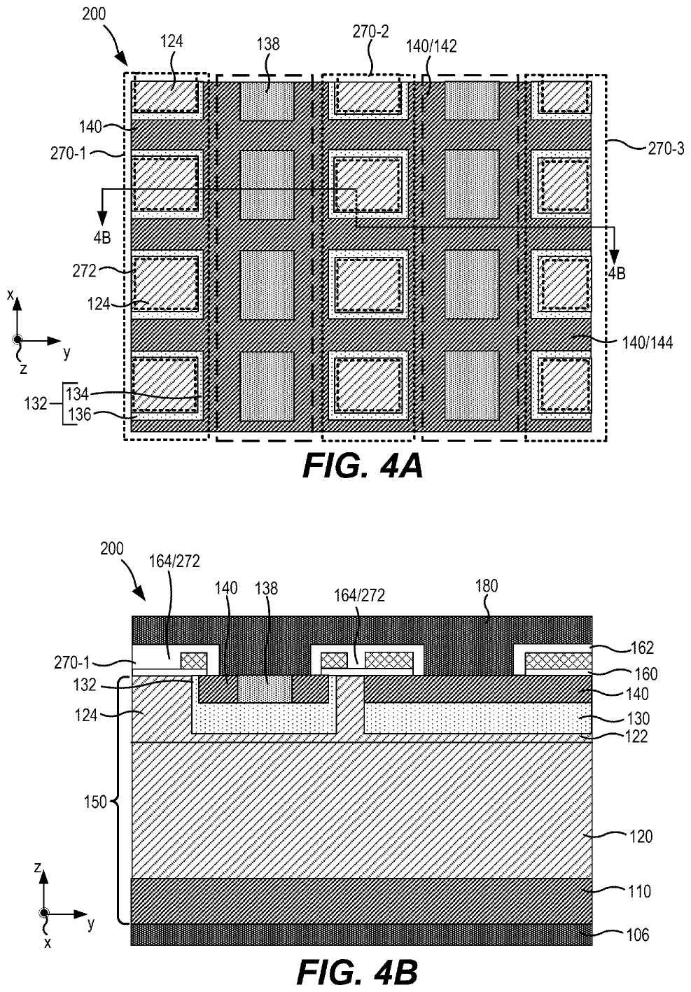

FIG. 4A is a schematic plan view of a portion of a top surface of a semiconductor layer structure 150 of a power MOSFET 200 according to further embodiments of the present invention. FIG. 4B is a schematic cross-sectional view taken along the line 4B 4B of FIG. 4A with portions of the upper metallization and dielectric layers of the power MOSFET 200 added for context.

Comparing FIGS. 4A-4B to FIGS. 3C-3D, it can be seen that power MOSFET 200 is similar to power MOSFET 100 of FIGS. 3A-3E, with the primary difference between power MOSFETs 100, 200 being that the gate electrodes 270 included in power MOSFET 200 have a plurality of first openings 272 formed therein. As best seen in FIG. 4A, each first opening 272 may expose a central portion of a respective one of the JFET regions 124. The gate electrodes 270, when viewed in plan view, may each cover the entirety of the ring-shaped channel regions 132 and may also cover the outer periphery of each JFET region 124 so that the channel regions 132 will be inverted when a voltage exceeding the threshold voltage of power MOSFET 200 is applied to the gate electrodes 270.

Referring again to power MOSFET 100 of FIGS. 3A-3E, during reverse blocking operation, electric fields extend upwardly from the drain contact 106 to the upper surface of the semiconductor layer structure 150. The p-wells 130 tend to block these electric fields (i.e., reduce the strength thereof), and thus the strongest electric fields are generated in the JFET regions 124, with the highest electric field values being present in the center of each JFET region 124 when the MOSFET 100 is viewed in plan view.

The inclusion of the first openings 272 in power MOSFET 200 removes the gate electrodes 270 from covering the central portions of each JFET region 124, thereby removing portions of a capacitor that is formed between the gate electrodes 270 and the semiconductor layer structure 150. The removal of the portions of the gate electrode 270 that overlie the central portion of each JFET region 124 acts to decrease the electric field values in these portions of MOSFET 200 which, in turn, acts to decrease the electric field values in the gate oxide layers 160 that overlie the JFET regions 124. Since these are the portions of the gate oxide layers 160 that would otherwise experience the highest electric field values during reverse blocking operation, it can be seen that the formation of the first openings 272 in the gate electrodes 270 acts to improve the reliability of MOSFET 200 as compared to MOSFET 100. While forming the first openings 272 in the gate electrodes 270 acts to reduce the overall amount of gate electrode material, thereby increasing the resistance of the gate electrodes 270, the increase in resistance is typically small, since the gate electrode 270 still includes wide transverse sections. Moreover, the size of the first openings 272 may be selected to optimize the tradeoff between gate resistance and reliability.

As shown in FIG. 4B, in power MOSFET 200 the intermetal dielectric patterns 162 may include additional portions 164 that fill the first openings 272 in the gate electrodes 270 so that the intermetal dielectric patterns 162 are disposed on top of the portions of the gate oxide layers 160 that cover the central portion of each JFET region 124. One way of improving the reliability of a power semiconductor device is to increase the thickness of the gate oxide layers 160. The provision of the portions 164 of the intermetal dielectric patterns 162 on top of the portions of the gate oxide layers 160 that cover the central portion of each JFET region 124 effectively results in a thicker oxide layer in these regions, thereby further improving the reliability of power MOSFET 200 as compared to power MOSFET 100. Moreover, the increase in thickness may be substantial (e.g., the oxide layer thickness may be doubled, tripled or more), and hence the improvement in reliability from the added dielectric material may be significant.

Thus, in MOSFET 200, the semiconductor layer structure 150 comprises a plurality of JFET regions 124 that have the first conductivity type, and each ring-shaped channel region 132 may surround a respective one of the JFET regions 124 when the MOSFET 100 is viewed in plan view. In addition, the first gate electrode 270-1 include a plurality of first openings 272, where each first opening 272 is above a respective one of the JFET regions 124. A dielectric layer 164 may be formed on upper surfaces of each of the JFET regions 124 in the respective first openings 272.

As power MOSFET 200 may otherwise be identical to power MOSFET 100, further description thereof will be omitted here.

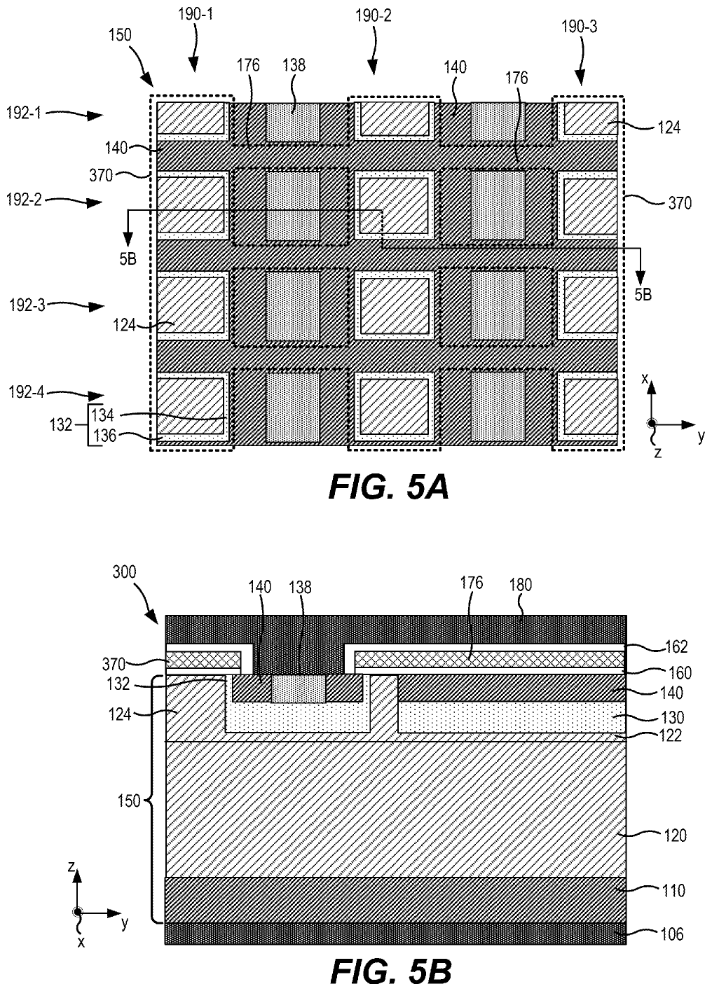

FIG. 5A is a schematic plan view of a top surface of the semiconductor layer structure 150 of a power MOSFET 300 according to additional embodiments of the present invention. FIG. 5B is a schematic cross-sectional view taken along the line 5B-5B of FIG. 5A with portions of the upper metallization and dielectric layers of the power MOSFET 300 added for context.

Comparing FIGS. 5A-5B to FIGS. 3C-3D, it can be seen that power MOSFET 300 is similar to power MOSFET 100 of FIGS. 3A-3E, with the primary difference between power MOSFETs 100, 300 being that power MOSFET 300 further includes a plurality of gate electrode connectors 176 so that power MOSFET 300 includes a continuous “mesh” gate electrode 370 whereas power MOSFET 100 includes a plurality of gate electrodes 170 that extend as stripes in parallel to each other. As can be seen by comparing FIGS. 3C and 5A, the design of the semiconductor layer structure 150 may be identical in power MOSFETs 100 and 300. The only difference between the two power MOSFETs 100, 300 is in the upper metallization, where the amount of gate electrode material is increased in power MOSFET 300 (by the addition of the gate electrode connectors 176) and the amount of source metallization is correspondingly decreased (and the design of the intermetal dielectric pattern 162 is changed in power MOSFET 300 to ensure that the gate connectors 176 and source metallization layer 180 are isolated from each other). The increased amount of gate electrode material in power MOSFET 300 reduces the gate resistance thereof, while the reduction in the amount of source metallization 180 acts to increase the on-state resistance. Thus, power MOSFETs having the mesh gate design of FIGS. 5A-5B may be used in applications where gate resistance drives performance more than on-state resistance.

As power MOSFET 300 may otherwise be identical to power MOSFET 100, further description thereof will be omitted here. It should also be noted that in further embodiments the gate electrode 370 of power MOSFET 300 may include first openings in the same locations that the gate electrodes 170 of power MOSFET 200 includes first openings 172, and the intermetal dielectric pattern 162 may fill these first openings in the same manner discussed above with reference to FIGS. 4A-4B.

Power MOSFETs 100 and 200 each have a stripe configuration, while power MOSFET 300 has a mesh configuration, which is a modified version of the stripe configuration. It will also be appreciated that the concepts discussed above may also be implemented in power MOSFETs and other power semiconductor devices that have a cell configuration.

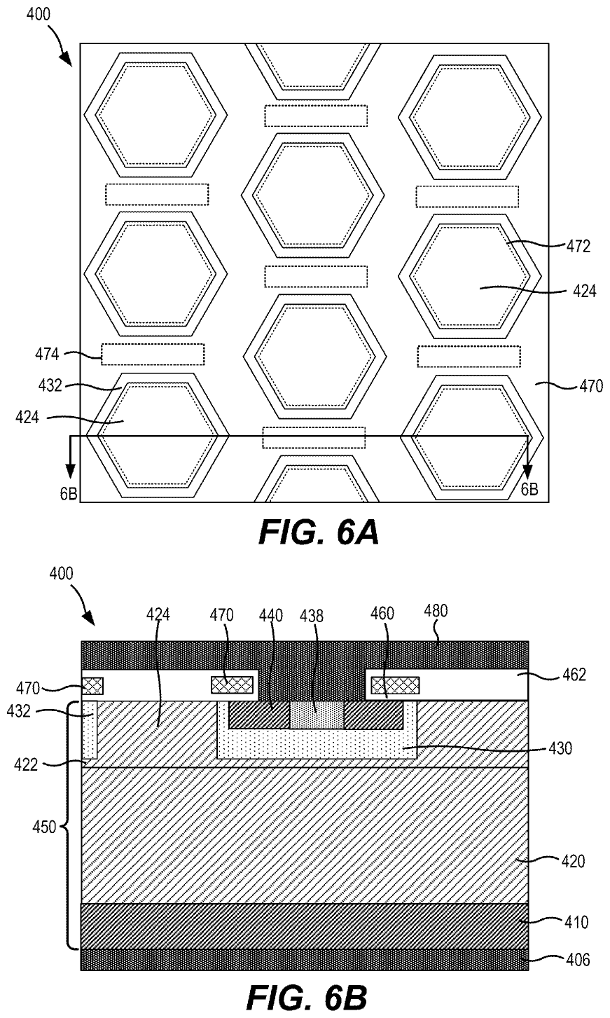

In particular, FIGS. 6A-6B illustrate a power MOSFET 400 according to embodiments of the present invention that has a cell configuration. In particular, FIG. 6A is a schematic plan view of power MOSFET 400 with certain of the upper metallization and dielectric layers omitted. FIG. 6B is a schematic cross-sectional view taken along the line 6B 6B of FIG. 6A with the upper metallization and dielectric layers of the power MOSFET 400 added for context.

Referring first to FIG. 6B, power MOSFET 400 includes a semiconductor layer structure 450 that includes a substrate 410, a drift region 420 that includes a current spreading layer 422 in an upper portion thereof, a continuous p-well 430, well contact regions 438, a continuous source region 440 that is within the p-well 430, and a plurality of JFET regions 424 (which are part of the drift region 420). The substrate 410, drift region 420, current spreading layer 422, JFET regions 424, p-well 430, well contact regions 438 and source region 440 may have the same conductivity types and doping concentrations as the corresponding substrate 110, drift region 120, current spreading layer 122, JFET regions 124, p-well 130, well contact regions 138 and source region 140 of power MOSFET 100 discussed above, but the shapes of various of these regions may differ, as can be seen by comparing FIGS. 3C-3D to FIGS. 6A-6B.

Referring to FIGS. 6A-6B, it can be seen that MOSFET 400 includes a plurality of ring-shaped channel regions 432 that are formed in upper outer regions of the continuous p-well 430. The continuous p-well 430 may extend throughout an active region 107 of power MOSFET 400. Each ring-shaped channel region 432, when viewed in plan view, may surround a respective one of the JFET regions 424, as best seen in FIG. 6A. This differs from the conventional design of a cell configuration vertical power MOSFET, which positions the source regions and well contact regions within the channel regions, and a continuous JFET region is provided outside the channel regions. The source region 440 is formed on the p-well 430 continuously throughout the active region 107 in the regions outside the ring-shaped channel regions 432.

Power MOSFET 400 has a single gate electrode 470 that extends continuously on the semiconductor layer structure 450 throughout the active region. In FIG. 6A, the dotted hexagons represent first openings 472 in the gate electrode 470. The first openings 472 expose portions of the interiors of the respective ring-shaped channel regions 432. The gate electrode, 470 further includes a plurality of second openings 474 that are shown as dotted rectangles in FIG. 6A. The second openings 474 expose selected portions of the source region 440 as well as a plurality of well contact regions 438. The second openings 474 are the regions where the source metallization layer 480 contacts the upper surface of the semiconductor layer structure 450.

In a conventional cell configuration power MOSFET, the source regions and well contact regions (collectively the “ohmic contact regions”) are within the interior of each of a plurality of ring-shaped channel regions. A continuous JFET region extends outside the ring-shaped channel regions. A continuous gate electrode extends over the continuous JFET region and over the ring-shaped channel regions. A plurality of first openings are provided in the gate electrode that expose a portion of the area inside each ring-shaped channel region 432. The source metallization layer extends into the first openings to contact the source regions and well contact regions. As can be seen, in power MOSFET 400 the locations of the JFET regions 424 and the ohmic contact region are reversed.

In power MOSFET 400, the amount of JFET region 424 (i.e., the cumulative area of the JFET regions 424 when viewed in plan view) may be reduced as compared to a conventional power MOSFET having a cell configuration. However, the amount of ohmic contact region may be increased, at least in some embodiments (depending on the size and number of second openings 474 in the gate electrode 470). In addition, as shown in FIG. 6A, the gate electrode 470 may not be formed over the interior portion of each JFET region 424. As discussed above with reference to MOSFET 200 of FIGS. 4A-4B, removing the gate electrode 470 from above the central portion of the JFET region 424 may act to reduce the electric field levels in the gate oxide layers 460 during reverse blocking operation, thereby improving the reliability of the power MOSFET 400. It will be appreciated that in other embodiments the gate electrode 470 may fully cover the JFET regions 424.

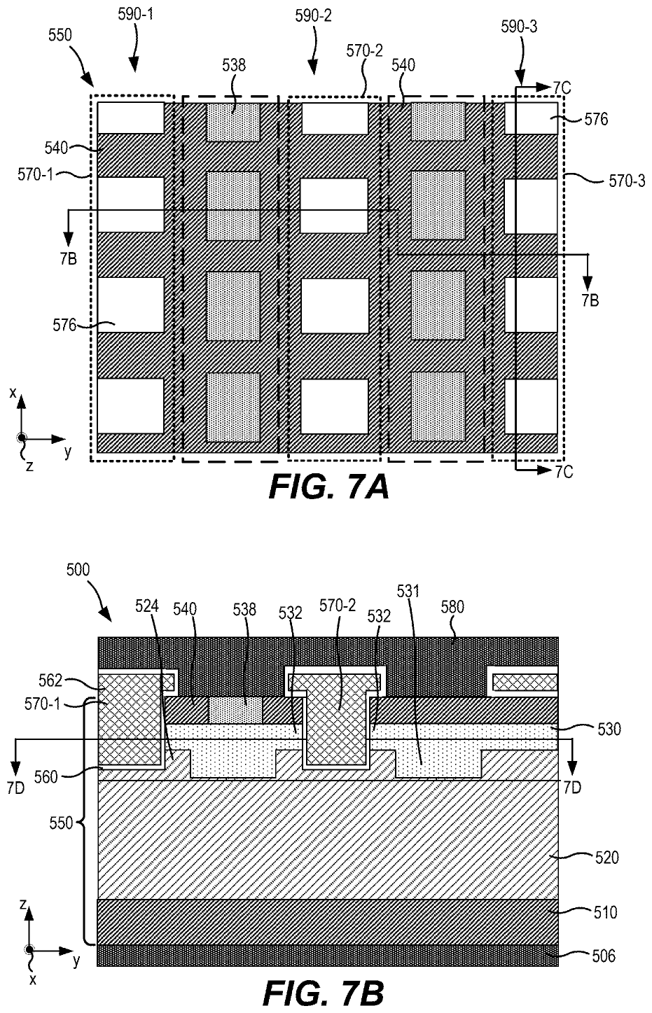

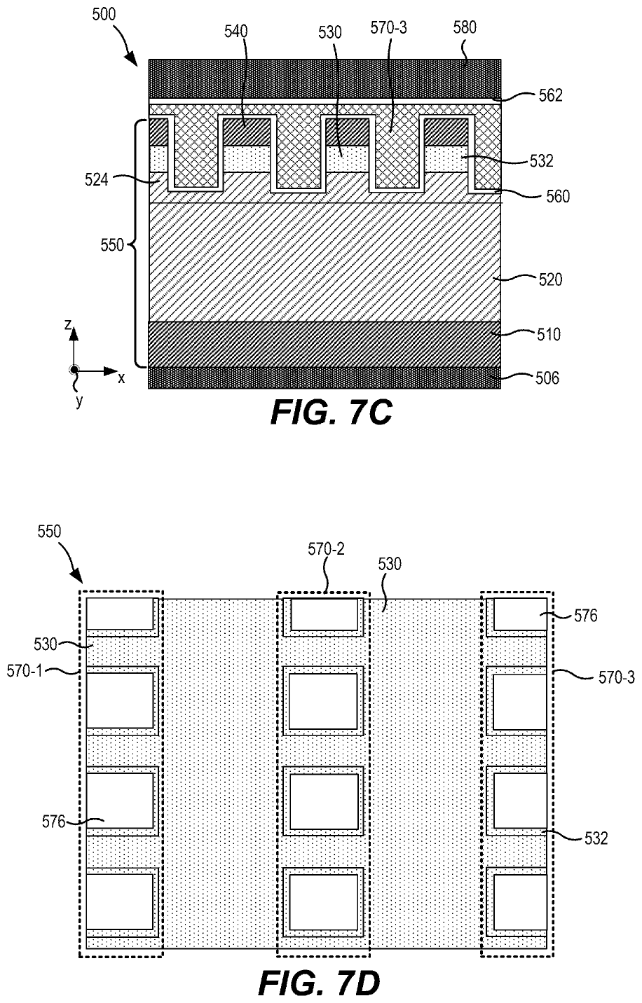

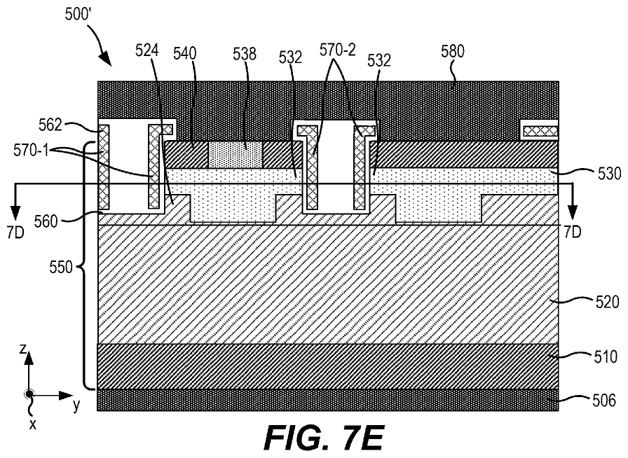

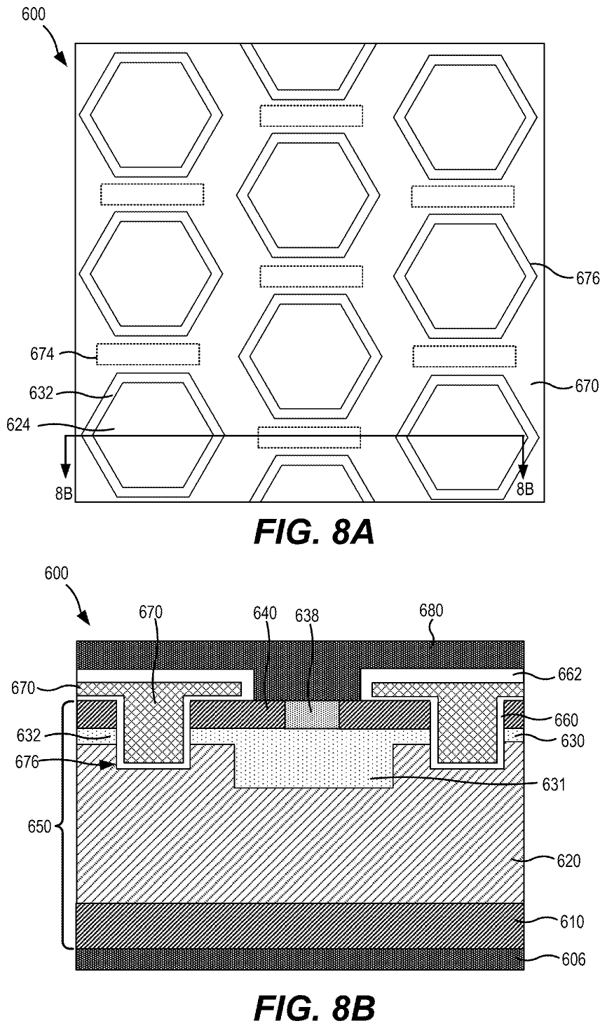

The above embodiments of the present invention are vertical power semiconductor devices that have planar gate electrode designs. It will be appreciated, however, that the same techniques discussed above may also be used in vertical power semiconductor devices that have trench gate electrode designs. Example embodiments of the present invention that have trench gate designs are illustrated in FIGS. 7A-8B.

FIG. 7A is a schematic plan view of a top surface of the semiconductor layer structure 550 of a power MOSFET 500 according to still further embodiments of the present invention. FIGS. 7B and 7C are schematic cross-sectional views taken along the lines 7B-7B and 7-7C, respectively, of FIG. 7A with portions of the upper metallization and dielectric layers of the power MOSFET 500 added for context. FIG. 7D is a schematic horizontal cross-section taken along line 7D-7D of FIG. 7B. Power MOSFET 500 is similar to power MOSFET 100 of FIGS. 3A-3E, except that power MOSFET 500 has a trench gate electrode design whereas power MOSFET 100 has a planar gate electrode design.

Power MOSFET 500 primarily differs from power MOSFET 100 in that a plurality of gate openings 576 are formed in the semiconductor layer structure 550. As shown in FIG. 7A, the gate openings 576 may be aligned in the column direction (the x-direction) to provide a plurality of columns 590 of gate openings 576. As shown in FIG. 7B, gate oxide layers 560 are formed in the gate openings 576 to line sidewalls and bottom surfaces of the gate openings 576. A respective gate electrode 570 may extend above each column 590 of gate openings 576, and may extend into each of the gate openings 576. In the depicted embodiment, the gate electrodes 570 cover the sidewalls and bottoms of each gate opening 576, and also fill the central region of each gate opening 576.

Still referring to FIG. 7B, it can be seen that power MOSFET 500 includes an n-type substrate 510 and an n-type drift region 520 which may have the same or similar doping concentrations as the n-type substrate 110 and n-type drift region 120, respectively, of power MOSFET 100. A p-well 530 is formed on an upper surface of the drift region 520. The p-well 530 may extend as a continuous p-well throughout an active region 107 of power MOSFET 500, as shown best in FIG. 7D. The p-well 530 includes deep implant portions 531 which may be more heavily doped than the remainder of p-well 530. A continuous source region 540 and a plurality of well contact regions 538 are formed in the upper portion of the p-well 530, and are part of a semiconductor layer structure 550 of MOSFET 500. The well contact regions 538 may appear as a plurality of “islands” in the source region 540 when the MOSFET 500 is viewed in plan view. It will be appreciated, however, that in other embodiments the well contact regions 538 may connect to each other along the x-direction so that a single elongated well contact region 538 is provided between each pair of adjacent gate electrodes 570. The source region 540 and well contact regions 538 may have the same or similar doping concentrations as source region 140 and well contact regions 138, respectively, of power MOSFET 100. As shown best in FIG. 7D, a plurality of ring-shaped channel regions 532 are formed in the portions of the p-well 530 that surround the respective gate openings 576. As shown best in FIGS. 7C-7D, the ring-shaped channel regions 532 are disposed underneath the source region 540 adjacent the gate openings 576. The ring-shaped channels 532 are vertical channels (i.e., current flows vertically through the channels) in contrast to the ring-shaped channels 132 of MOSFET 100, which are horizontal channels. JFET regions 524 are defined underneath each ring-shaped channel region 532, where the JFET region 524 is the region in between lower portions of the p-well 530 and the gate openings 576. Each JFET region 524 may have a ring shape so that each JFET region 524 extends around a respective one of the gate openings 576 underneath respective ones of the ring-shaped channel regions 532.

Still referring to FIGS. 7A-7D, the MOSFET 500 further includes a drain contact 506 and a source metallization layer 580 which may be similar or identical to the drain contact 106 and source metallization layer 180, respectively, of MOSFET 100.

As shown in FIGS. 7A-7D, power MOSFET 500 includes a semiconductor layer structure 550 that comprises a drift region 520 having a first conductivity type and a plurality of ring-shaped channel regions 532 having a second conductivity type on the drift region 520, where a first plurality of gate openings 576 are provided in an upper surface of the semiconductor layer structure 550. Power MOSFET 500 further includes a gate electrode 570-1 that extends into the gate openings 576 in the first plurality of gate openings 576. Each ring-shaped channel region 532 surrounds a respective one of the first plurality of gate openings 576 when power MOSFET 500 is viewed in plan view, as can best be seen in FIG. 7D. The gate electrode 570-1 is a first gate electrode, and power MOSFET 500 further includes a second gate electrode 570-2 that extends in parallel to the first gate electrode 570-1. A second plurality of gate openings 576 are provided in the upper surface of the semiconductor layer structure 550 and the second gate electrode 570-2 extends into the gate openings 576 in the second plurality of gate openings 576. The semiconductor layer structure 550 further comprises a continuous well region 530 having the second conductivity type that extends underneath both the first and second gate electrodes 570-1, 570-2.

As can also be seen from FIGS. 7A-7D, power MOSFET 500 includes a semiconductor layer structure 550 comprising a drift region 520 having a first conductivity type, a well region 530 having a second conductivity type on the drift region 520 and a source region 540 having first conductivity type in the well region 530. The semiconductor layer structure 550 includes a plurality of gate openings 576 in an upper surface thereof, where the gate openings 576 are arranged to form a plurality of columns 590 of gate openings 576. A gate electrode 570-1 extends into the gate openings 576 in a first of the columns 590 of gate openings 576. A plurality of ring-shaped channel regions 532 surround the respective gate openings 576.

FIG. 7E is a schematic cross-sectional view of a power MOSFET 500′ that is a modified version of the power MOSFET 500 of FIGS. 7A-7D where FIG. 7E corresponds to the cross-section of FIG. 7B. As can be seen by comparing FIGS. 7B and 7E, power MOSFETs 500 and 500′ are very similar to each other, with the difference being that in power MOSFET 500 the gate electrodes fill each gate opening 576 whereas in power MOSFET 500′ the gate electrodes only cover the sidewalls (note that in the depicted embodiment each gate opening 576 has four sidewalls since the gate openings 576 have a rectangular shape) of the gate openings 576 and the center of each gate opening 576 is filled by the intermetal dielectric pattern 562. This acts to effectively increase the thickness of the gate oxide layers 560 in the center portion of each gate opening 576, since the intermetal dielectric pattern 562 contacts the gate oxide layers 560 in the center portion of each gate opening 576 thereby effectively increasing the thickness of the gate oxide layers in these regions. Since during reverse blocking operation the highest electric fields will form in the gate oxide layer above the center of the bottom surface of each gate opening 576, the (effective) increased thickness of the gate oxide layer in these regions may act to improve the reliability of the power MOSFET by increasing the time to breakdown. It should be noted that while gate electrode 570-1 appears as two unconnected strips in the cross-section of FIG. 7E, these strips are connected to each other outside the gate openings 576, as can be seen by the fact the gate electrode 570-2 extends continuously in the lateral (y) direction in FIG. 7E.

FIG. 8A is a schematic plan view of a power MOSFET 600 according to embodiments of the present invention with certain of the upper metallization and dielectric layers omitted. FIG. 8B is a schematic cross-sectional view taken along the line 8B-8B of FIG. 8A with the upper metallization and dielectric layers of the power MOSFET 600 added for context.

Power MOSFET 600 is similar to power MOSFET 400, except that power MOSFET 600 has a trench gate design, and the first openings 472 in the gate electrode 470 of power MOSFET 400 are omitted in power MOSFET 600. Thus, as shown FIG. 8A, power MOSFET 600 has a gate electrode 670 that extends continuously throughout the active region and that has second openings 674 that expose ohmic contact sections of a semiconductor layer structure 650. A plurality of columns of gate openings 676 are formed in the semiconductor layer structure 650. Ring-shaped channel regions 632 surround each gate opening 676. Ring-shaped JFET regions 624 are provided beneath the ring-shaped channel regions 632. Each ring-shaped JFET region 624 surrounds a respective one of the gate openings 676. The second openings 674 that expose ohmic contact sections of a semiconductor layer structure 650 are formed outside of the ring-shaped channel regions 632.

Referring to FIG. 8B, the semiconductor layer structure 650 includes a substrate 610, a drift region 620, JFET regions 624, a continuous p-well 630, well contact regions 638 and a continuous source region 640. The substrate 610, drift region 620, JFET regions 624, p-well 630, well contact regions 638 and source region 640 may have the same conductivity types and doping concentrations as the corresponding substrate 110, drift region 120, current spreading layer 122, JFET regions 124, p-well 130, well contact regions 138 and source region 140 of power MOSFET 100 discussed above, but the shapes of various of these regions may differ. The p-wells 630 may also include deep shielding portions 631 that may be more highly doped than other portions of the p-wells 630.

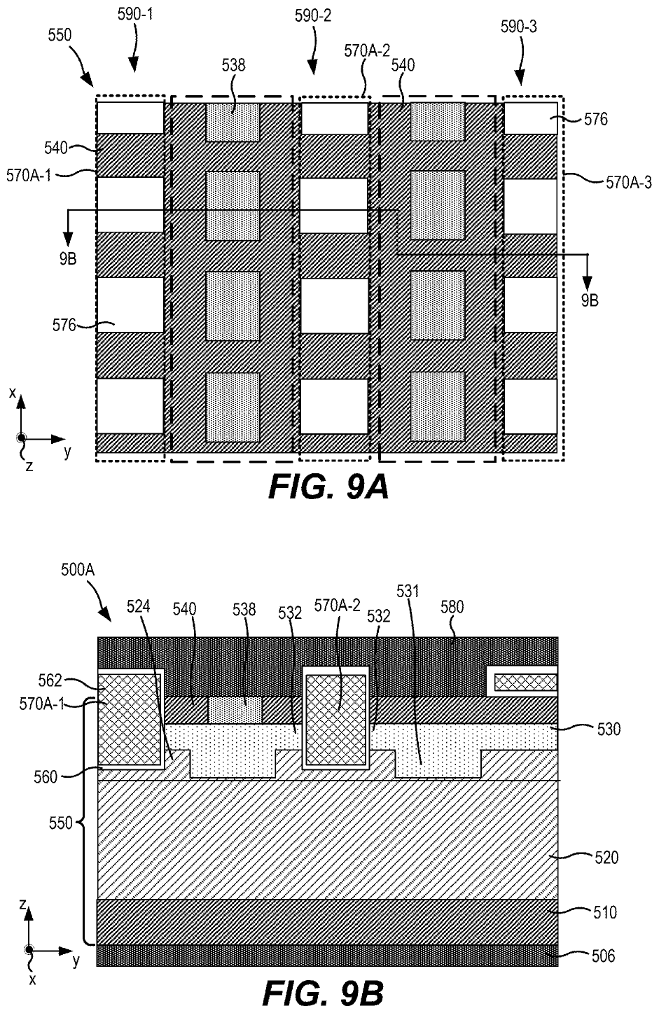

FIG. 9A is a schematic plan view of a portion of a top surface of the semiconductor layer structure 550 of a power MOSFET 500A according to still further embodiments of the present invention. FIG. 9B is a schematic cross-sectional view taken along line 9B-9B of FIG. 9A with portions of the upper metallization and dielectric layers of the power MOSFET 500A added for context. MOSFET 500A is a slightly modified version of MOSFET 500 of FIGS. 7A-7E. Comparing FIGS. 7A-7B to FIGS. 9A-9B, it can be seen that power MOSFET 500A is identical to power MOSFET 500 of FIGS. 7A-7E, except that the widths of the gate electrodes 570A are reduced in MOSFET 500A so that the gate electrodes 570A have about the same width as the gate openings 576. This change increases the size of the openings between adjacent gate electrodes 570A allowing the source metallization 580 to contact a greater percentage of the upper surface of the semiconductor layer structure 550. This may help decrease the source resistance, but the thinner gate electrodes 570A may have increased gate resistance. Thus, the width of the gate electrodes may be optimized based on a desired tradeoff between source on-state resistance and gate resistance.

In the above description, MOSFETs having ring-shaped channel regions are described where the ring-shaped channel regions have rectangular or hexagonal shapes when viewed in plan view (i.e., the channel regions are annular rectangles when viewed from above). It will be appreciated that embodiments of the present invention are not limited thereto, and that the ring-shaped channel regions may have a wide variety of different ring shapes. For example, in other embodiments, the embodiments the ring-shaped channel regions may have circular shapes, oval shapes, octagonal shapes or polygonal shapes having rounded corners when viewed from above. The ring-shaped channel regions may also have more complex shapes and/or may be asymmetric when viewed from above. Any of the power MOSFETs disclosed herein may be modified to have any of the above-described ring-shaped channel regions in further embodiments of the present invention.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure comprising a drift region having a first conductivity type, a plurality of channel regions that each have a second conductivity type, and a plurality of JFET regions that each have the first conductivity type,
wherein each channel region comprises a ring-shaped channel region that has a ring shape and surrounds a respective one of the JFET regions when viewed in plan view.

2. The semiconductor device of claim 1, wherein the ring-shaped channel regions are arranged as a plurality of columns of ring-shaped channel regions when viewed in plan view.

3-5. (canceled)

6. The semiconductor device of claim 2, further comprising:
a first gate electrode that extends on an upper surface of the semiconductor layer structure above a first of the columns of ring-shaped channel regions; and
a second gate electrode that extends on the upper surface of the semiconductor layer structure above a second of the columns of ring-shaped channel regions,
where a longitudinal axis of the first gate electrode is parallel to a longitudinal axis of the second gate electrode.

7. The semiconductor device of claim 6, wherein the first gate electrode includes a plurality of first openings, where each first opening is above a respective one of the JFET regions.

8. (canceled)

9. The semiconductor device of claim 6, wherein the first gate electrode is separated from the second gate electrode in a transverse direction, and wherein a width of each ring-shaped channel region in the transverse direction is larger than a distance between adjacent ring-shaped channel regions in the first of the columns of ring-shaped channel regions.

10. (canceled)

11. The semiconductor device of claim 1, wherein the ring-shaped channel regions are upper regions of a well region having the second conductivity type that is formed on the drift region, and the JFET regions are within openings in the well region.

12. The semiconductor device of claim 11, wherein the well region is a single continuous region within an active region of the semiconductor device.

13. The semiconductor device of claim 12, the semiconductor layer structure further comprising a continuous source region that extends throughout the active region on the well region.

14. The semiconductor device of claim 13, wherein the continuous source region comprises a plurality of longitudinally-extending stripes and a plurality of transversely-extending connecting segments, and the transversely-extending connecting segments connect adjacent longitudinally-extending stripes.

15. (canceled)

16. The semiconductor device of claim 1, further comprising a continuous gate electrode that extends throughout an active region of the semiconductor device.

17-19. (canceled)

20. A semiconductor device, comprising:
a semiconductor layer structure comprising a drift region having a first conductivity type and a plurality of channel regions having a second conductivity type, where each channel region includes, in plan view, a first segment that extends in a first direction and a second segment that extends in a second direction that is different from the first direction;
a first gate electrode that has a first longitudinal axis on an upper surface of the semiconductor layer structure; and
a second gate electrode that has a second longitudinal axis on an upper surface of the semiconductor layer structure, the second longitudinal axis extending in parallel to the first longitudinal axis.

21-22. (canceled)

23. The semiconductor device of claim 20, wherein each channel region is a ring-shaped channel region that has a ring shape when viewed in plan view.

24. The semiconductor device of claim 23, wherein the semiconductor layer structure further comprises a plurality of JFET regions that have the first conductivity type, and each ring-shaped channel region surrounds a respective one of the JFET regions when viewed in plan view.

25-26. (canceled)

27. The semiconductor device of claim 23, wherein the first gate electrode vertically overlaps a first sub-set of the ring-shaped channel regions, and the second gate electrode vertically overlaps a second sub-set of the ring-shaped channel regions.

28. The semiconductor device of claim 27, wherein the first sub-set of the ring-shaped channel regions defines a first column of ring-shaped channel regions and the second first sub-set of the ring-shaped channel regions defines a second column of ring-shaped channel regions.

29-47. (canceled)

48. A semiconductor device, comprising:
a semiconductor layer structure comprising a drift region having a first conductivity type, a well region having a second conductivity type on the drift region, and a plurality of spaced-apart JFET regions having the first conductivity type;
a first gate electrode that extends on an upper surface of the semiconductor layer structure above a first sub-set of the spaced-apart JFET regions; and
a second gate electrode that extends on an upper surface of the semiconductor layer structure above a second sub-set of the spaced-apart JFET regions,
where a longitudinal axis of the first gate electrode is parallel to a longitudinal axis of the second gate electrode.

49. The semiconductor device of claim 48, wherein the first gate electrode includes a plurality of first openings, where each first opening is above a respective one of the JFET regions.

50. The semiconductor device of claim 49, wherein a dielectric layer is formed on an upper surface of each of the JFET regions in the respective first openings.

51. The semiconductor device of claim 48, wherein the semiconductor layer structure further comprises a plurality of ring-shaped channel regions that are provided in an upper portion of the well region, where each ring-shaped channel region surrounds a respective one of the JFET regions when the semiconductor device is viewed in plan view.

52. The semiconductor device of claim 51, wherein the first gate electrode is separated from the second gate electrode in a transverse direction, and wherein a width of each ring-shaped channel region in the transverse direction is larger than a distance between adjacent ones of the ring-shaped channel regions that vertically overlap the first gate electrode.

53-63. (canceled)
